(19) United States
(12) Patent Application Publication
(10) Pub. No.: US 2020/0328137 A1
(43) Pub. Date: Oct. 15, 2020

(54) HEAT DISSIPATING MODULE WITH MICRO-PASSAGES

(71) Applicant: JIA LONG (PING TANG) TECH., FU ZHOU CITY (CN)

(72) Inventor: HAI LAN, FU ZHOU CITY (CN)

(21) Appl. No.: 16/528,866

(22) Filed: Aug. 1, 2019

(30) Foreign Application Priority Data
Apr. 10, 2019 (CN) 201910283812.4

(51) Int. Cl. H01L 23/427; H01L 23/467; F28D 15/02; H05K 7/20; F28F 3/02

(52) U.S. Cl. CPC H01L 23/427; H01L 23/467; F28D 2021/0028; H05K 7/2029; F28F 3/02; F28D 15/0266

(57) ABSTRACT

A heat dissipating module with micro-passages includes a heat dissipating cavity connecting to a top of a heat absorbing cavity to form a distance from a heat source. When a working fluid in the heat absorbing cavity absorbs the thermal energy and is vaporized, the vapor would flow up to a vapor guiding space due to thermosyphon effect and principles of Boyle's Law, and then the vapor is projected and spread rapidly and evenly to the heat dissipating cavity through a projecting exit. Then the vapor is condensed into liquid and become the working fluid again by heat exchange. The condensed liquid then drips down and flows back to the heat absorbing cavity via micro-passages, forming a cycle of phase change of the working fluid for operation of heat dissipation.

### BACKGROUND OF THE INVENTION

### 1. Field of the Invention

The invention relates to a heat dissipating module, especially to one that has a structure of micro-passages and forms a distance from the heat source to the dissipating fins.

### 2. Description of the Related Art

As technology advanced, nowadays the chips installed on electronic devices have increased, causing higher temperature of the devices during operations. To avoid problems resulted from high temperature, heat pipes are commonly used in the field for heat dissipation. Such heat pipes conduct and transfer the thermal energy by the latent heat produced from phase changes of the working fluids. At the vaporization section of the heat pipes, the working fluids obtain a huge amount of thermal energy from the heat source by vaporizing the latent heat and then release the thermal energy and condense into liquid at the condensation section of the heat pipes. The working fluids would flow back to the vaporization section due to the wick structure and capillary actions of liquids. Such operation is repeated within the heat pipes for continuous heat dissipation.

FIG. 1 illustrated a conventional heat dissipating module 10 in one-dimension. The module 10 has a plurality of dissipating fins 12 arranged at a rear end of a pipe 11 and has a front end extended to have contact with a heating device (not shown). When the front end absorbs the thermal energy from the heating device, the energy is transmitted to the rear end for dissipating the heat by the dissipating fins 12. Although such operation can dissipate the heat in some degree, it cannot achieve certain efficiency since the rear end of the pipe 11 has the worst thermal conductivity. On the other hand, due to the design of the pipe 11, the working fluid inside the pipe 11 would stay at the rear end when going through phase changes, and the thermal energy cannot be conducted and transferred to the fins 12 effectively, causing ineffective results of the dissipation.

FIG. 2 illustrated a conventional heat dissipating module 20 in two-dimension. The module 20 mainly includes an upper board 21 and a lower board 22, and the surface of the upper board 21 are chipped and cut to form a plurality of dissipating find 23. When the upper and lower boards 21, 22 are assembled, a hollow chamber 24 is formed therein, so that when the lower board 22 is contacting with a heating device (not shown), the thermal energy would be absorbed by the lower board 22 and conducted to the upper board 21 via the hollow chamber 24. Then the thermal energy is further conducted and transferred to the fins 23 for dissipation. Such modules do have greater efficiency than the one shown in FIG. 1, but as the power of electronic devices such as light-emitting diodes getting higher and being applied to huge devices like fishing light attractors, lighting projectors and projectors, the dissipating efficiency of such modules still requires improvements.

### SUMMARY OF THE INVENTION

It is a primary objective of the present invention to provide a heat dissipating module with micro-passages that has a three-dimensional structure for a heat dissipating section to be arranged at a distance from a heat source, so as to enhance the heat dissipation function and reduce the side effect that conventional heat dissipation modules may cause to the applied products.

It is another objective of the present invention to provide a heat dissipating module with micro-passages that has a structure applied with the principles of thermosyphon and Boyle's Law to project vapor rapidly and evenly for heat dissipation.

In order to achieve the above objectives, the heat dissipating module with micro-passages includes a heat absorbing cavity vertically arranged as a bottom section thereof arranged to be contacted with a heat source and filled with a working fluid, said heat absorbing cavity further including a vertical vapor guiding space formed in a middle of said heat absorbing cavity in a conic shape as a top thereof arranged as a projecting exit; a heat dissipating cavity connecting a top of said heat absorbing cavity and further connecting with said projecting exit of said heat absorbing cavity, thereby being far from said bottom section of said heat absorbing cavity, said heat dissipating cavity including a plurality of fins on a top surface thereof for heat dissipation; and at least one micro-passage arranged along an inner periphery of said heat absorbing cavity and connecting to said heat dissipating cavity by an upper section thereof and to said bottom section of said heat absorbing cavity by a lower section thereof.

Whereby when the working fluid absorbs the thermal energy from the heat source, the working fluid is vaporized and the vapor is guided to flow upwards through the vapor guiding space and then, based on the thermosyphon effect, projected from the projecting exit and spread rapidly and evenly to the heat dissipating cavity for the fins to perform heat dissipation; then the vapor in the heat dissipating cavity further goes through a heat exchange process and is condensed back to liquid form for dripping and flowing back to the heat absorbing cavity via the upper section and then the lower section of the at least one micro-passage and becoming the working fluid again, so as to form a cycle of the heat dissipating module.

In the first applicable embodiment, the at least one micro-passage is formed by a tube structure arranged along an inner periphery of the heat absorbing cavity and a one-way valve is disposed neat the lower section of the tube structure of the micro-passage. In the second applicable embodiment, the at least one micro-passage is formed by a layer of microporous structure arranged on an inner periphery of the heat absorbing cavity.

Furthermore, an inner periphery of the vapor guiding space further has a surface with micro structure, or the inner periphery of the vapor guiding space further has a helix structure thereon.

Also, the bottom section of the heat absorbing cavity includes a bottom surface and a periphery extended upwards from said bottom surface in order to be contacted with different heat sources.

Based on the thermosyphon effect and the principles of Boyle's Law, the present invention has the vapor flow upwards to the heat dissipating cavity rapidly and evenly through the vapor guiding space to be projected from the projecting exit. And the structure of the heat dissipating cavity being arranged at a distance from the heat source features even greater efficiency in heat dissipation and less side effects to the products it is installed on during operation. The present invention is thereby suitable for LED lighting fixtures and electronic devices with high power rates.

### BRIEF DESCRIPTION OF THE DRAWINGS

FIG. 1 is a schematic diagram illustrating structure of a one-dimensional heat dissipating module according to the prior art;

FIG. 2 is a schematic diagram illustrating structure of a two-dimensional heat dissipating module according to the prior art;

FIG. 3 is a schematic diagram illustrating structure of the present invention in a first applicable embodiment;

FIG. 4 is a schematic diagram illustrating a working fluid vaporized in the first applicable embodiment;

FIG. 5 is a schematic diagram illustrating vapor condensed to liquid and flowing back to become the working fluid again, thereby forming a cycle of phase change according to the first applicable embodiment;

FIG. 6A is a schematic diagram illustrating operation of a projecting exit of the present invention in the first applicable embodiment;

FIG. 6B is a schematic diagram illustrating a vapor guiding space of the present invention in an applicable embodiment;

FIG. 6C is a schematic diagram illustrating the vapor guiding space of the present invention in another applicable embodiment;

FIG. 7 is a schematic diagram illustrating structure of the present invention in a second applicable embodiment;

FIG. 8 is schematic diagram illustrating the working fluid vaporized in the second applicable embodiment;

FIG. 9 is a schematic diagram illustrating vapor condensed to liquid and flowing back to become the working fluid again, thereby forming a cycle of phase change according to the second applicable embodiment; and

FIG. 10 is a schematic diagram illustrating the cycle of phase change according to the second applicable embodiment.

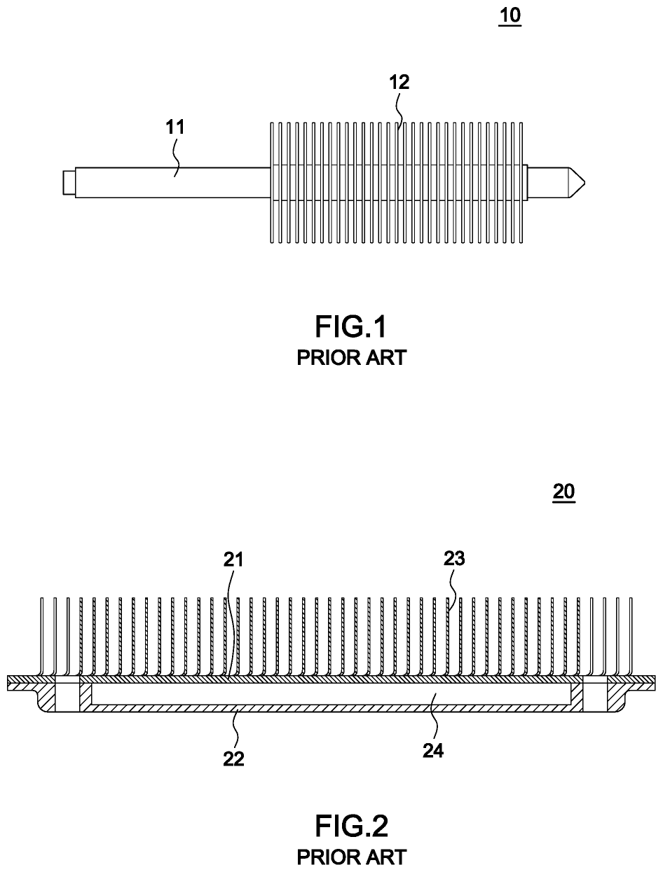

### DETAILED DESCRIPTION OF THE PREFERRED EMBODIMENT

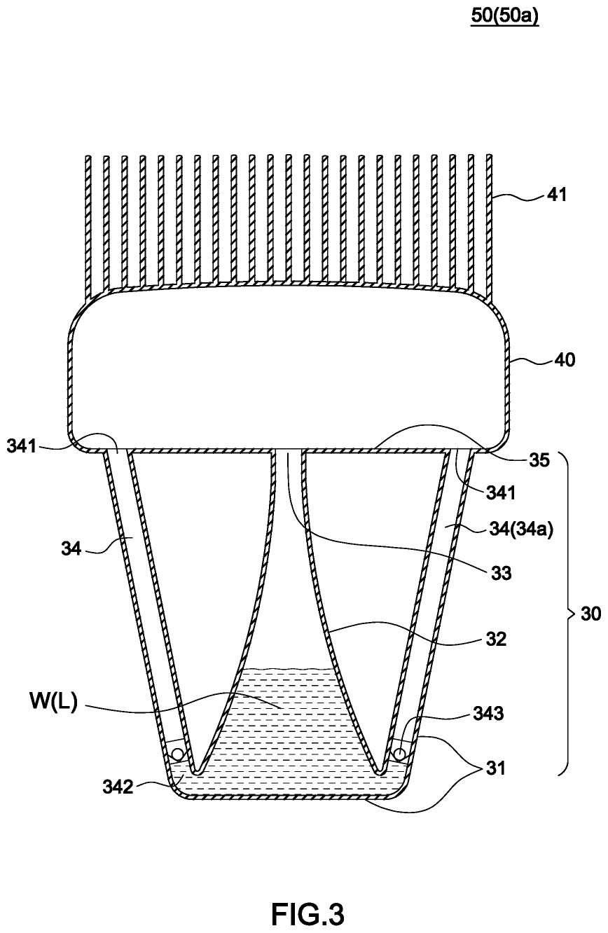

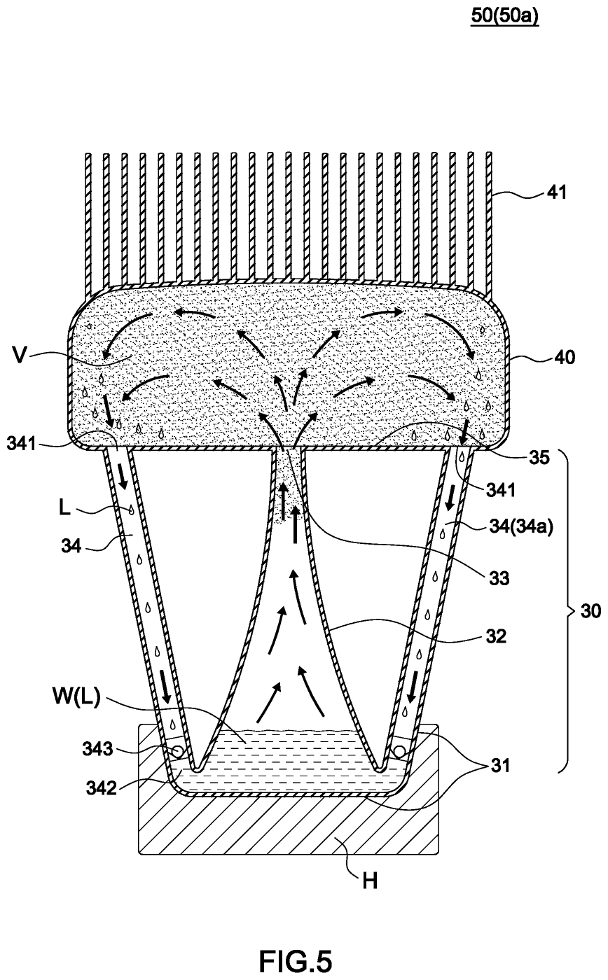

Referring to FIGS. 3-6, in a first applicable embodiment, a heat dissipating module with micro-passages 50 mainly includes a heat absorbing cavity 30, a heat dissipating cavity 40 and at least one micro-passage 34.

The heat absorbing cavity 30 is vertically arranged as a bottom section 31 thereof arranged to be contacted with a heat source H and filled with a working fluid W. The heat absorbing cavity 30 further includes a vertical vapor guiding space 32 formed in a middle thereof in a conic shape as a top thereof arranged as a projecting exit 33. In this embodiment, the shape of the heat absorbing cavity 30 can be circular or polygonal and the projecting exit 33 is formed by having the top of the vapor guiding space 32 concentrated to an exit with a shorter diameter. The bottom section 31 includes a bottom surface and a periphery extended upwards from the bottom surface in order to be contacted with different heat sources.

The working fluid W is selected from a group including pure water, ammonia solution, methyl alcohol, isopropyl alcohol and heptane liquid; it is also applicable to add heat conductive particles in the working fluid W to enhance the dissipation function. Such particles include copper particles, carbon nanotube, carbon nanocapsules, and the carbon nanotube and the carbon nanocapsules may further contain copper particles in nanometer degrees filled therein. But the present invention is not limited to such application.

The heat dissipating cavity 40 is connecting a top 35 of the heat absorbing cavity 30 and further connecting with the projecting exit 33 of the heat absorbing cavity 30, thereby being far from the bottom section 31 of the heat absorbing cavity 30. The heat dissipating cavity 40 further includes a plurality of fins 41 on a top surface thereof for heat dissipation. In this embodiment, the shape of the heat dissipating cavity 40 is arranged in accordance with the shape of the heat absorbing cavity 30.

The at least one micro-passage 34 is arranged along an inner periphery of the heat absorbing cavity 30 and connecting to the heat dissipating cavity 40 by an upper section 341 thereof and to the bottom section 31 of the heat absorbing cavity 30 by a lower section 342 thereof. In this embodiment, the at least one micro-passage 34 is formed by a tube structure 34a arranged along an inner periphery of the heat absorbing cavity 30. In another preferred embodiment, a one-way valve 343 is further disposed neat the lower section 342 of the tube structure 34a of the micro-passage 34, but the present invention is not limited to such application. With the one-way valve 343, the vapor V would be condensed into liquid L and flow back down to the heat absorbing cavity 30 without going in upward direction. Since the present invention is designed with the structures based on application of the thermosyphon effect and the principles of Boyle's Law, the projecting exit 33 can be arranged to form an exit to project the vapor V upwards with high pressure to complete a cycle of phase change for dissipation; therefore, the possibility of the condensed liquid L in the heat dissipating cavity 40 flowing in the counter direction is substantially low.

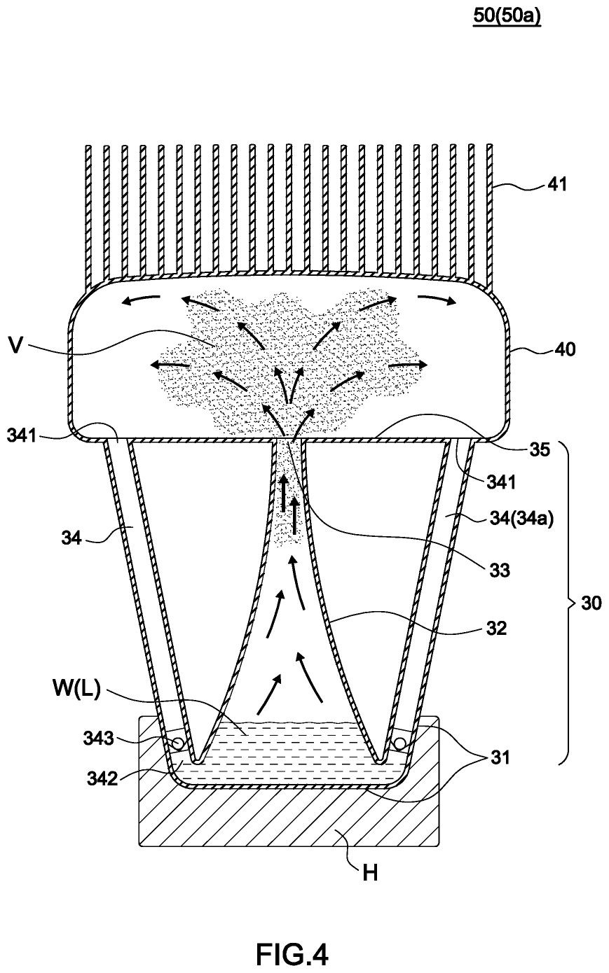

With reference to FIG. 4 when the working fluid W absorbs the thermal energy from the heat source H, the working fluid W is vaporized and the vapor V is guided to flow upwards through the vapor guiding space 32 and then projected from the projecting exit 33 and spread rapidly and evenly to the heat dissipating cavity 40 for the fins 41 to perform heat dissipation based on the thermosyphon effect; then the vapor V in the heat dissipating cavity 40 further goes through a heat exchange process and is condensed back to liquid form L; by the gravity force or capillary phenomenon, the liquid L would drip and flow back to the heat absorbing cavity 30 via the upper section 341 and then the lower section 342 of the at least one micro-passage 34 and becoming the working fluid W again, so as to form a cycle of phase change for operation of the heat dissipating module 50a.

The thermosyphon is the process of producing a pushing force by density difference. The density difference is further formed by heating up the working fluid W by a heating source H to cause partial of the working fluid W vaporized and thereby reducing the density. When the working fluid W is heated, its volume is increased and its weight is also lighter, causing a rising phenomenon; then the colder fluid nearby would fill in the space and thereby form the cycle to produce the force repeatedly.

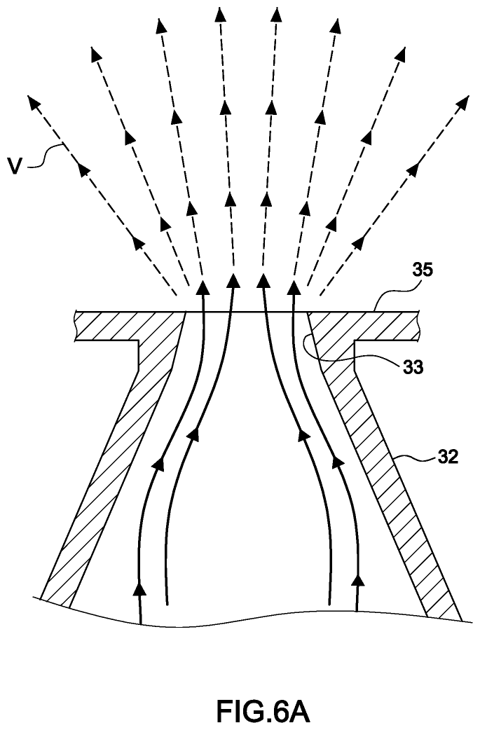

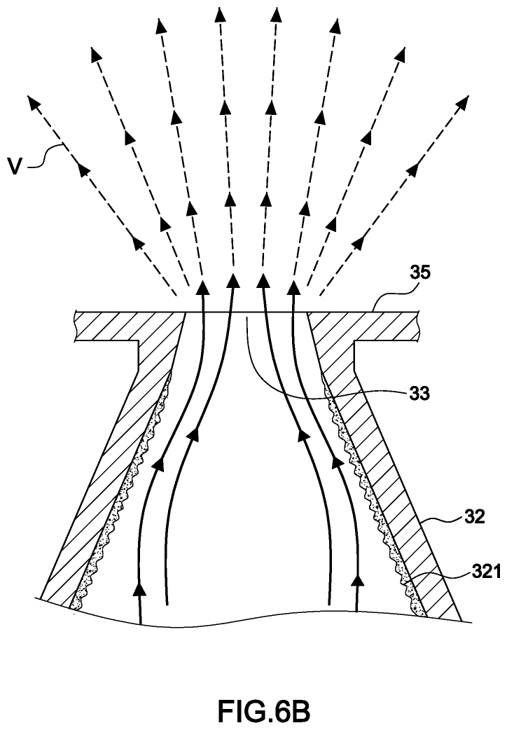

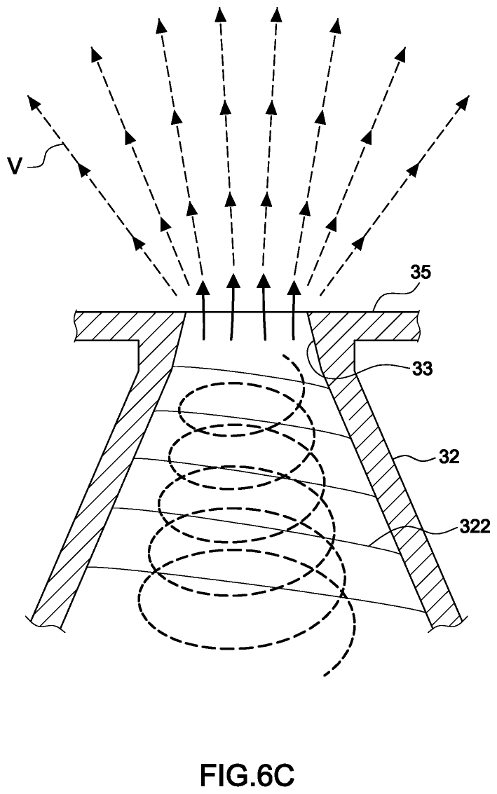

Referring to FIG. 6, according to the compressibility of air and the Boyle's Law, the volume of compressible air is in inverse proportion to the force of pressure; and the design of the projecting exit 33 is exactly a structure of a compressor for the vapor V in the vapor guiding space 32. The vapor V is thereby projected and spread rapidly and evenly from the projecting exit 33 due to sudden change of the pressure and the volume caused by the density difference. Then the vapor V is further spread in the heat dissipating cavity 40 for the fins 41 to perform dissipation efficiently.

FIG. 6B illustrated another applicable embodiment of structure of the vapor guiding space 32. An inner periphery of the vapor guiding space 32 further has a surface with micro structure 321 such as rough surface and microporous surface. Thereby the vapor V is able to flow through the vapor guiding space 32 even more smoothly and to be spread evenly and rapidly after projected via the projecting exit 33 for greater efficiency of dissipation.

In another applicable embodiment as shown in FIG. 6C, an inner periphery of the vapor guiding space 32 further has a helix structure 322 thereon. The helix structure 322 is like the rifling on the inner surface of a gun's barrel to allow the vapor V to spin within the vapor guiding space 32 and then to be further projected from the projecting exit 33. With the spinning movement, the vapor V can be spread rapidly and evenly for greater efficiency of dissipation.

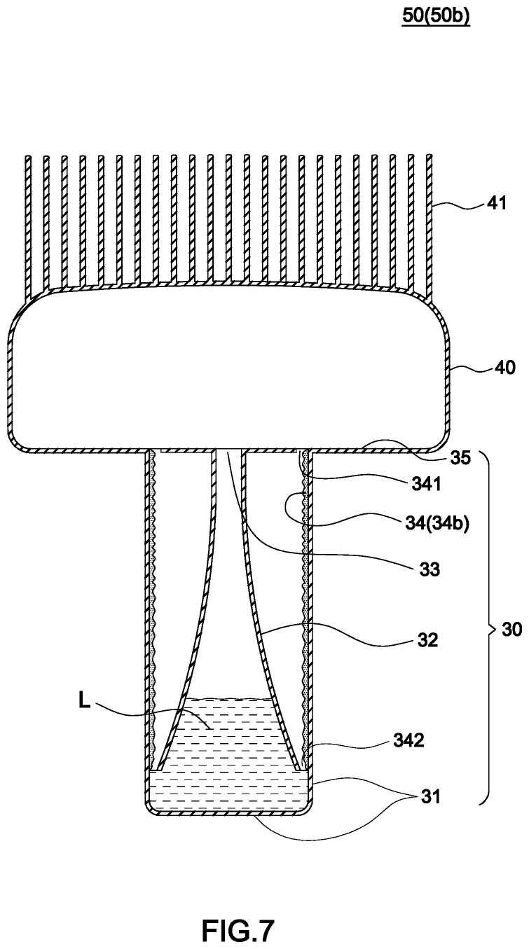

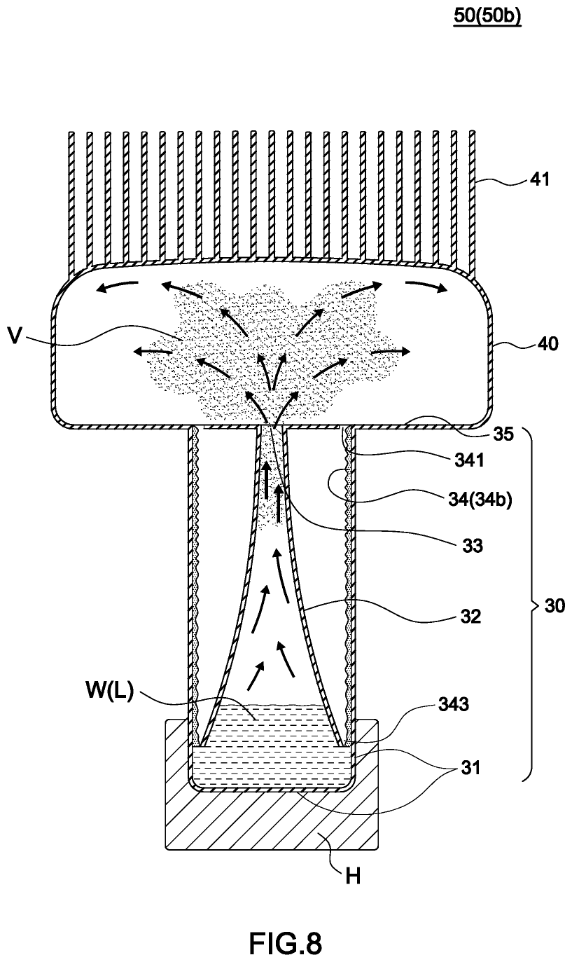

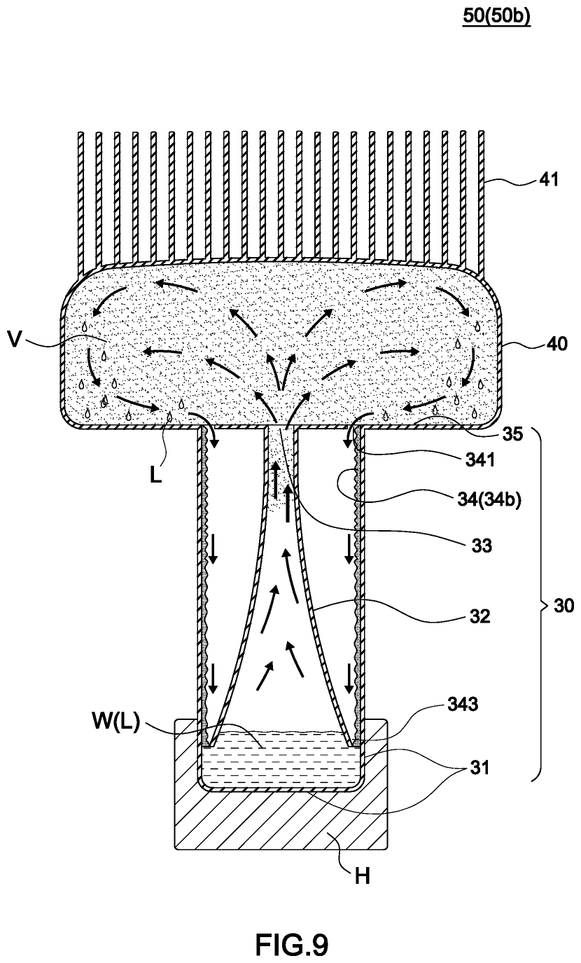

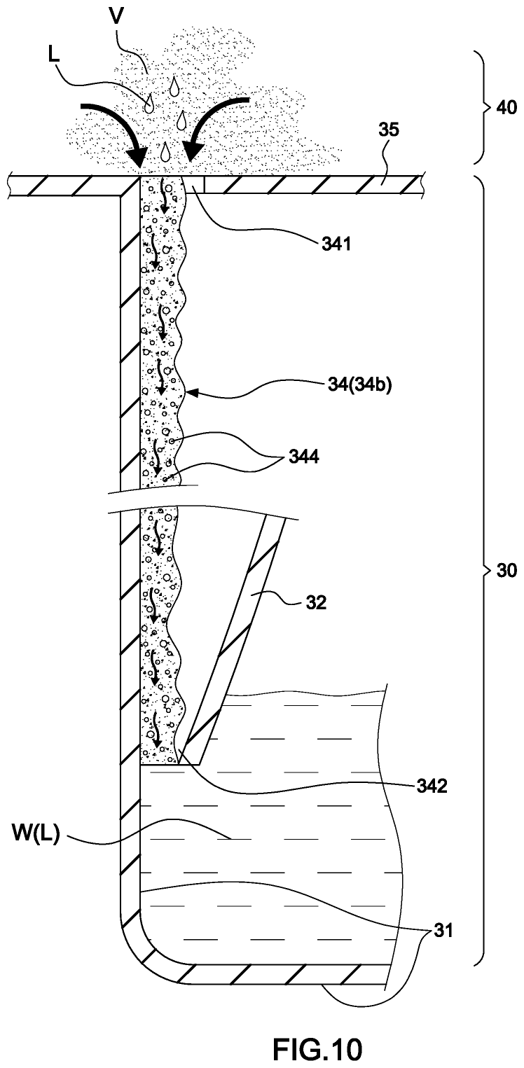

FIGS. 7-10 illustrated a second applicable embodiment of the heat dissipating module with micro-passages 50. The difference between the embodiments disclosed above and this embodiment is that the at least one micro-passage 34 is formed by a layer of microporous structure 34b arranged on the inner periphery of the heat absorbing cavity 30. In this embodiment, the micro-passage 34 is constructed by the layer of microporous structure 34b which has a plurality of micro pores formed by methods such as sintering. The function of the microporous layer 34b is the same as the tube structure 34a in the first applicable embodiment—to allow the vapor V to perform heat exchange in the heat dissipating cavity 40 and to be condensed to liquid form L; then the liquid L would drip and flow back to the heat absorbing cavity 30 via the upper section 341 and then the lower section 342 of the at least one micro-passage 34 by the gravity force or capillary phenomenon and become the working fluid W again, so as to form a cycle of phase change for operation of the heat dissipating module 50b.

In short, the structure of the heat dissipating module 50 combines the thermosyphon effect and the design of the projecting exit 33 based on Boyle's Law to guide the vapor produced from heated working fluid W flowing upwards through the vapor guiding space 32, being projected from the projecting exit 33 and spread to the heat dissipating cavity 40 rapidly and evenly. Such design can dissipate the heat efficiently and is especially suitable for LED lighting fixtures and electronic devices with high power. Additionally, the heat dissipating cavity 40 is arranged at a distance from the heat source H to enhance the efficiency of dissipation and to reduce the side effects the module might cause to the products it is installed on, further controlling the temperature in some degree.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A heat dissipating module with micro-passages, comprising:
a heat absorbing cavity vertically arranged as a bottom section thereof arranged to be contacted with a heat source and filled with a working fluid, said heat absorbing cavity further including a vertical vapor guiding space formed in a middle of said heat absorbing cavity in a conic shape as a top thereof arranged as a projecting exit;
a heat dissipating cavity connecting a top of said heat absorbing cavity and further connecting with said projecting exit of said heat absorbing cavity, thereby being far from said bottom section of said heat absorbing cavity, said heat dissipating cavity including a plurality of fins on a top surface thereof for heat dissipation; and
at least one micro-passage arranged along an inner periphery of said heat absorbing cavity and connecting to said heat dissipating cavity by an upper section thereof and to said bottom section of said heat absorbing cavity by a lower section thereof;
whereby when the working fluid absorbs the thermal energy from the heat source, the working fluid is vaporized and the vapor is guided to flow upwards through the vapor guiding space and then projected from the projecting exit and spread rapidly and evenly to the heat dissipating cavity for the fins to perform heat dissipation; then the vapor in the heat dissipating cavity further goes through a heat exchange process and is condensed back to liquid form for dripping and flowing back to the heat absorbing cavity via the upper section and then the lower section of the at least one micro-passage and becoming the working fluid again, so as to form a cycle of the heat dissipating module.

2. The heat dissipating module with micro-passages as claimed in claim 1, wherein the at least one micro-passage is formed by a tube structure arranged along an inner periphery of the heat absorbing cavity.

3. The heat dissipating module with micro-passages as claimed in claim 2, wherein a one-way valve is disposed neat the lower section of the tube structure of the micro-passage.

4. The heat dissipating module with micro-passages as claimed in claim 1, wherein the at least one micro-passage is formed by a layer of microporous structure arranged on an inner periphery of the heat absorbing cavity.

5. The heat dissipating module with micro-passages as claimed in claim 1, wherein an inner periphery of the vapor guiding space further has a surface with micro structure.

6. The heat dissipating module with micro-passages as claimed in claim 1, wherein an inner periphery of the vapor guiding space further has a helix structure thereon.

7. The heat dissipating module with micro-passages as claimed in claim 1, wherein the bottom section of the heat absorbing cavity includes a bottom surface and a periphery extended upwards from said bottom surface in order to be contacted with different heat sources.
